(19) United States
(12) Patent Application Publication
(10) Pub. No.: US 2015/0235914 A1
(43) Pub. Date: Aug. 20, 2015

(54) FLIP-CHIP PACKAGING SUBSTRATE, FLIP-CHIP PACKAGE AND FABRICATION METHODS THEREOF

(71) Applicant: Siliconware Precision Industries Co., Ltd., Taichung (TW)

(72) Inventors: Chang-Fu Lin, Taichung (TW); Chin-Tsai Yao, Taichung (TW); Ming-Chin Chuang, Taichung (TW); Po-Hua Chen, Taichung (TW); Fu-Tang Huang, Taichung (TW)

(21) Appl. No.: 14/328,092

(22) Filed: Jul. 10, 2014

(30) Foreign Application Priority Data
Feb. 17, 2014 (TW) 103105072

(51) Int. Cl. H01L 23/13; H05K 3/46; H05K 1/11; C25D 5/02; H01L 23/00; H01L 21/48

(52) U.S. Cl. CPC H01L 23/13; H01L 24/17; H01L 24/81; H01L 21/4857; H05K 1/111; H05K 1/119; C25D 5/02; H05K 3/4661; H01L 2924/014; H01L 2924/01029; H01L 2924/37001; H05K 2201/10674

(57) ABSTRACT

A flip-chip packaging substrate is provided, which includes: a substrate body; a plurality of conductive pads formed on a surface of the substrate body; an insulating layer formed on the surface of the substrate body and having a plurality of openings correspondingly exposing a portion of each of the conductive pads; and a metal layer formed on each of the conductive pads in the openings, wherein the metal layer has a top surface having a lowest point lower than a top surface of the insulating layer, and a thickness ratio of the metal layer to the insulating layer is greater than or equal to 1/4 and less than 1, thereby preventing a solder bridge or short circuit from occurring.

### BACKGROUND OF THE INVENTION

1. Field of the Invention The present invention relates to packaging substrates, packages and fabrication methods thereof, and more particularly, to a flip-chip packaging substrate, a flip-chip package and fabrication methods thereof.

2. Description of Related Art

FIG. 1 is a schematic cross-sectional view of a conventional flip-chip package. Referring to FIG. 1, a plurality of conductive pads 11 are formed on a surface of a substrate body 10, and an insulating layer 12 is formed on the surface of the substrate body 10 and has a plurality of openings 120 exposing a portion of each of the conductive pads 11. The insulating layer 12 has a thickness of about 20 to 30 um. Further, a semiconductor chip 14 is mounted on the substrate body 10 through a plurality of solder bumps 13.

However, during a reflow process of the solder bumps, the volume of the solder bumps expands by about 30 to 50%. Therefore, the solder material easily flows out between the insulating layer and the conductive pads or between the insulating layer and the substrate body, thus resulting in a solder extrusion. As such, if the pitch between adjacent conductive pads is small, a solder bridge easily occurs between the adjacent conductive pads, thereby resulting in a short circuit and reducing the product yield.

In another conventional flip-chip package (not shown), a plurality of copper pillars can be formed on the conductive pads and protrude above a top surface of the insulating layer, and a semiconductor chip can be electrically connected to the conductive pads through the copper pillars. However, when a lateral force is applied to such a package, it easily causes separation of the copper pillars from the conductive pads. As such, the product yield is reduced.

Therefore, how to overcome the above-described drawbacks has become critical.

### SUMMARY OF THE INVENTION

In view of the above-described drawbacks, the present invention provides a flip-chip packaging substrate, which comprises: a substrate body; a plurality of conductive pads formed on a surface of the substrate body; an insulating layer formed on the surface of the substrate body and having a plurality of openings correspondingly exposing a portion of each of the conductive pads; and a metal layer formed on each of the conductive pads in the openings, wherein the metal layer has a top surface having a lowest point lower than a top surface of the insulating layer, and a thickness ratio of the metal layer to the insulating layer is greater than or equal to ¼ and less than 1.

The present invention further provides a method for fabricating a flip-chip packaging substrate, which comprises the steps of: forming a plurality of conductive pads on a surface of a substrate body; forming an insulating layer on the surface of the substrate body, wherein the insulating layer has a plurality of openings correspondingly exposing a portion of each of the conductive pads; and forming a metal layer on each of the conductive pads in the openings, wherein the metal layer has a top surface having a lowest point lower than a top surface of the insulating layer, and a thickness ratio of the metal layer to the insulating layer is greater than or equal to ¼ and less than 1.

The present invention further provides a flip-chip package, which comprises: a substrate body; a plurality of conductive pads formed on a surface of the substrate body; an insulating layer formed on the surface of the substrate body and having a plurality of openings correspondingly exposing a portion of each of the conductive pads; a metal layer formed on each of the conductive pads in the openings, wherein the metal layer has a top surface having a lowest point lower than a top surface of the insulating layer, and a thickness ratio of the metal layer to the insulating layer is greater than or equal to ¼ and less than 1; and a semiconductor chip electrically connected to the metal layer on the conductive pads through a plurality of solder bumps.

The present invention further provides a method for fabricating a flip-chip package, which comprises the steps of: providing a flip-chip packaging substrate, which comprises: a substrate body; a plurality of conductive pads formed on a surface of the substrate body; an insulating layer formed on the surface of the substrate body and having a plurality of openings correspondingly exposing a portion of each of the conductive pads; and a metal layer formed on each of the conductive pads in the openings, wherein the metal layer has a top surface having a lowest point lower than a top surface of the insulating layer, and a thickness ratio of the metal layer to the insulating layer is greater than or equal to ¼ and less than 1; and electrically connecting a semiconductor chip to the metal layer on the conductive pads through a plurality of solder bumps.

The present invention can reduce the volume of the solder material so as to reduce the expansion volume of the solder material. Further, the present invention lengthens the path between adjacent solder bumps. Therefore, the present invention prevents a solder bridge or short circuit from occurring even if a solder extrusion phenomenon occurs.

### BRIEF DESCRIPTION OF DRAWINGS

FIG. 1 is a schematic cross-sectional view of a conventional flip-chip package;

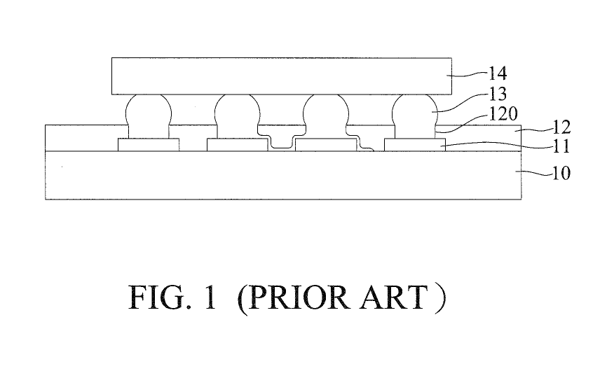

FIGS. 2A to 2C are schematic cross-sectional views showing different embodiments of a flip-chip packaging substrate of the present invention, wherein FIG. 2A′ is a schematic cross-sectional view showing a fabrication process of the packaging substrate of FIG. 2A; and

FIG. 3 is a schematic cross-sectional view of a flip-chip package of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms used in the present invention are merely for illustrative purposes and should not be construed to limit the scope of the present invention.

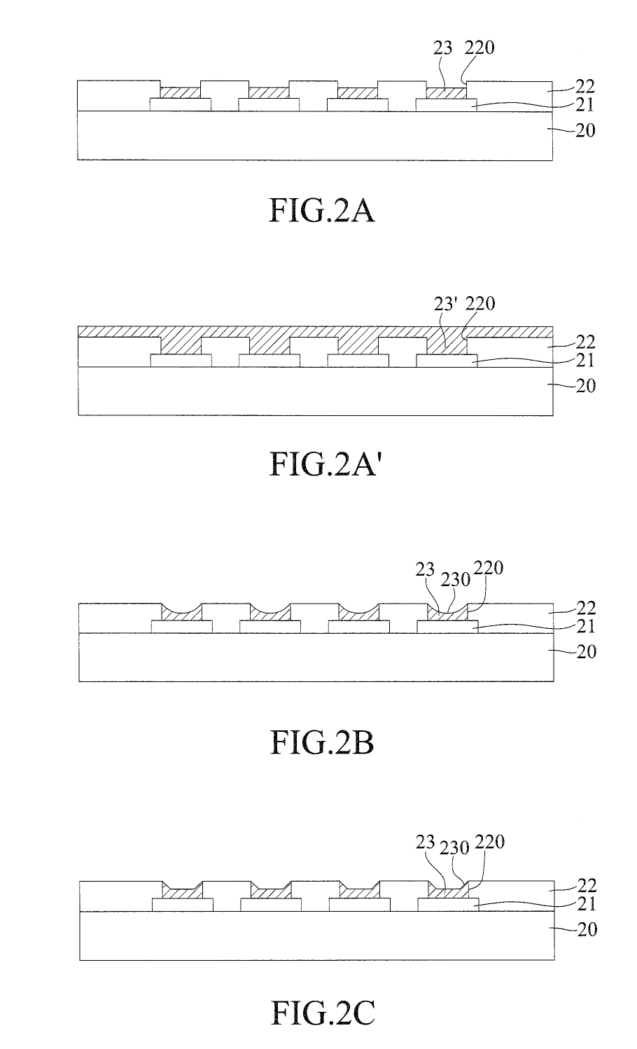

FIGS. 2A to 2C are schematic cross-sectional views showing different embodiments of a flip-chip packaging substrate of the present invention.

Referring to FIGS. 2A to 2C, the flip-chip packaging substrate has: a substrate body 20; a plurality of conductive pads 21 formed on a surface of the substrate body 20; an insulating layer 22 formed on the surface of the substrate body 20 and having a plurality of openings 220 exposing a portion of each of the conductive pads 21; and a metal layer 23 formed on each of the conductive pads 21 in the openings 220, wherein the metal layer 23 has a top surface having a lowest point lower than a top surface of the insulating layer 22.

According to the present invention, a method for fabricating the flip-chip packaging substrate includes: forming a plurality of conductive pads 21 on a surface of the substrate body 20; forming an insulating layer 22 on the surface of the substrate body 20, wherein the insulating layer 22 has a plurality of openings 220 exposing a portion of each of the conductive pads 21; and forming a metal layer 23 on each of the conductive pads 21 in the openings 220 by coating or electroplating, wherein the metal layer 23 has a top surface having a lowest point lower than a top surface of the insulating layer 22.

In the above-described method, the metal layer 23 can be formed to a predefined thickness by electroplating. In another embodiment, forming the metal layer 23 includes: forming a metal stud 23′ (as shown in FIG. 2A′) on each of the conductive pads 21 in the openings 220; and removing a portion of the metal stud 23′ from top by such as etching so as to form the metal layer 23.

In the above-described flip-chip packaging substrate and fabrication method thereof, the metal layer 23 can be made of such as copper and have a thickness between 4 and 20 um. The thickness ratio of the metal layer 23 to the insulating layer 22 is greater than or equal to ¼ and less than 1. Preferably, the thickness ratio of the metal layer 23 to the insulating layer 22 is between ⅓ and ¾.

In the above-described packaging substrate and fabrication method thereof, the thickness of the metal layer 23 is the distance from the lowest point of the top surface of the metal layer 23 to the top surface of the conductive pad 21. The thickness ratio of the metal layer 23 to the insulating layer 22 is the thickness of the metal layer 23 divided by the thickness of the insulating layer 22. The minimum effective thickness ratio of the metal layer 23 to the insulating layer 22 is equal to ¼. If the thickness ratio of the metal layer 23 to the insulating layer 22 is equal to 1, i.e., the thickness of the metal layer 23 is equal to the thickness of the insulating layer 22, it becomes difficult to receive and fix a solder bump on the metal layer 23. As such, the solder material easily flows outward. Therefore, the thickness ratio of the metal layer 23 to the insulating layer 22 should be less than 1. Preferably, the thickness ratio of the metal layer 23 to the insulating layer 22 is between ⅓ and ¾. As such, the metal layer 23 achieves sufficient thickness and the insulating layer 22 provides sufficient receiving space for receiving a solder bump.

Referring to FIGS. 2B and 2C, the metal layer 23 extends to a wall of the corresponding opening 220. Further, a recess 230 is formed on the top surface of the metal layer 23. The top surface of the metal layer 23 has a highest point flush with the top surface of the insulating layer 22. Referring to FIG. 2B, the recess 230 can be of a bowl shape. Alternatively, referring to FIG. 2C, the recess 230 can be wide at top and narrow at bottom and have flat bottom and side surfaces.

Further, a surface finish (not shown) can be formed on the metal layer 23. The surface finish can be made of Ni/Au, Ni/Pd/Au or OSP (Organic Solderability Preservative).

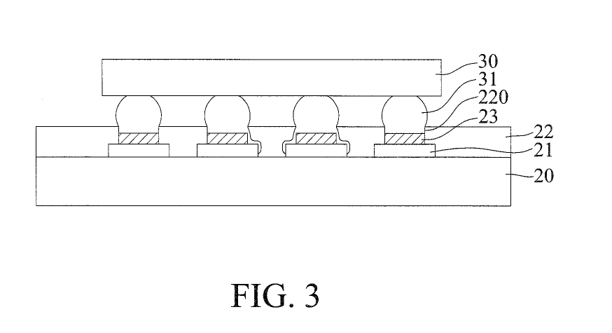

FIG. 3 is a schematic cross-sectional view of a flip-chip package of the present invention. Referring to FIG. 3, the flip-chip package has: a substrate body 20; a plurality of conductive pads 21 formed on a surface of the substrate body 20; an insulating layer 22 formed on the surface of the substrate body 20 and having a plurality of openings 220 exposing a portion of each of the conductive pads 21; a metal layer 23 formed on each of the conductive pads 21 in the openings 220, wherein the metal layer 23 has a top surface having a lowest point lower than a top surface of the insulating layer 22; and a semiconductor chip 30 electrically connected to the metal layer 23 on the conductive pads 21 through a plurality of solder bumps 31.

According to the present invention, a method for fabricating a flip-chip package includes: providing a flip-chip packaging substrate of the present invention, and electrically connecting a semiconductor chip to the metal layer 23 on the conductive pads 21 through a plurality of solder bumps 31.

According to the present invention, if the surface finish is made of Ni/Au or Ni/Pd/Au, during reflow of the solder bumps 31, the surface finish can be melted into the solder bumps 31. On the other hand, if the surface finish is made of OSP, the surface finish must be removed before mounting the solder bumps 31 and the semiconductor chip 30.

Therefore, by forming a metal layer on each of the conductive pads, the present invention reduces the volume of the solder material so as to reduce the expansion volume of the solder material. Further, referring to FIG. 3, by increasing the contact area between the metal layer and the insulating layer, the present invention lengthens the path between adjacent solder bumps so as to prevent a solder bridge or short circuit from occurring even if a solder extrusion phenomenon occurs. Therefore, the product yield is increased. Furthermore, since the solder wetting surface is lower than the top surface of the insulating layer, stresses can be dispersed to avoid separation of the metal layer from the conductive pads.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A flip-chip packaging substrate, comprising:
a substrate body;
a plurality of conductive pads formed on a surface of the substrate body;
an insulating layer formed on the surface of the substrate body and having a plurality of openings correspondingly exposing a portion of each of the conductive pads; and
a metal layer formed on each of the conductive pads in the openings, wherein the metal layer has a top surface having a lowest point lower than a top surface of the insulating layer, and a thickness ratio of the metal layer to the insulating layer is greater than or equal to ¼ and less than 1.

2. The substrate of claim 1, wherein the thickness ratio of the metal layer to the insulating layer is between ⅓ and ¾.

3. The substrate of claim 1, further comprising a recess formed on the top surface of the metal layer.

4. The substrate of claim 3, wherein the recess is of a bowl shape.

5. The substrate of claim 3, wherein the recess is wide at top and narrow at bottom and has flat bottom and side surfaces.

6. The substrate of claim 1, wherein the metal layer extends to a wall of the corresponding opening.

7. The substrate of claim 6, wherein the top surface of the metal layer has a highest point flush with the top surface of the insulating layer.

8. The substrate of claim 1, further comprising a surface finish formed on the metal layer.

9. The substrate of claim 1, wherein the metal layer is made of copper.

10. A method for fabricating a flip-chip packaging substrate, comprising the steps of:
forming a plurality of conductive pads on a surface of a substrate body;
forming an insulating layer on the surface of the substrate body, wherein the insulating layer has a plurality of openings correspondingly exposing a portion of each of the conductive pads; and
forming a metal layer on each of the conductive pads in the openings, wherein the metal layer has a top surface having a lowest point lower than a top surface of the insulating layer, and a thickness ratio of the metal layer to the insulating layer is greater than or equal to ¼ and less than 1.

11. The method of claim 10, wherein the metal layer is formed to a predefined thickness by electroplating.

12. The method of claim 10, wherein forming the metal layer comprises:
forming a metal stud on each of the conductive pads in the openings; and
removing a portion of the metal stud from top to form the metal layer.

13. The method of claim 12, wherein the portion of the metal stud is removed by etching.

14. The method of claim 10, wherein the thickness ratio of the metal layer to the insulating layer is between ⅓ and ¾.

15. The method of claim 10, wherein a recess is formed on the top surface of the metal layer.

16. The method of claim 15, wherein the recess is of a bowl shape.

17. The method of claim 15, wherein the recess is wide at top and narrow at bottom and has flat bottom and side surfaces.

18. The method of claim 10, wherein the metal layer extends to a wall of the corresponding opening.

19. The method of claim 18, wherein the top surface of the metal layer has a highest point flush with the top surface of the insulating layer.

20. The method of claim 10, further comprising forming a surface finish on the metal layer.

21. The method of claim 10, wherein the metal layer is made of copper.

22. A flip-chip package, comprising:
a substrate body;
a plurality of conductive pads formed on a surface of the substrate body;
an insulating layer formed on the surface of the substrate body and having a plurality of openings correspondingly exposing a portion of each of the conductive pads;
a metal layer formed on each of the conductive pads in the openings, wherein the metal layer has a top surface having a lowest point lower than a top surface of the insulating layer, and a thickness ratio of the metal layer to the insulating layer is greater than or equal to ¼ and less than 1; and
a semiconductor chip electrically connected to the metal layer on the conductive pads through a plurality of solder bumps.

23. The package of claim 22, wherein the thickness ratio of the metal layer to the insulating layer is between ⅓ and ¾.

24. The package of claim 22, further comprising a recess formed on the top surface of the metal layer.

25. The package of claim 24, wherein the recess is of a bowl shape.

26. The package of claim 24, wherein the recess is wide at top and narrow at bottom and has flat bottom and side surfaces.

27. The package of claim 22, wherein the metal layer extends to a wall of the corresponding opening.

28. The package of claim 27, wherein the top surface of the metal layer has a highest point flush with the top surface of the insulating layer.

29. The package of claim 22, wherein the metal layer is made of copper.

30. A method for fabricating a flip-chip package, comprising the steps of:
providing a flip-chip packaging substrate, which comprises:
a substrate body;
a plurality of conductive pads formed on a surface of the substrate body;
an insulating layer formed on the surface of the substrate body and having a plurality of openings correspondingly exposing a portion of each of the conductive pads; and
a metal layer formed on each of the conductive pads in the openings, wherein the metal layer has a top surface having a lowest point lower than a top surface of the insulating layer, and a thickness ratio of the metal layer to the insulating layer is greater than or equal to ¼ and less than 1; and
electrically connecting a semiconductor chip to the metal layer on the conductive pads through a plurality of solder bumps.

31. The method of claim 30, wherein the thickness ratio of the metal layer to the insulating layer is between ⅓ and ¾.

32. The method of claim 30, wherein a recess is formed on the top surface of the metal layer.

33. The method of claim 32, wherein the recess is of a bowl shape.

34. The method of claim 32, wherein the recess is wide at top and narrow at bottom and has flat bottom and side surfaces.

35. The method of claim 30, wherein the metal layer extends to a wall of the corresponding opening.

36. The method of claim 35, wherein the top surface of the metal layer has a highest point flush with the top surface of the insulating layer.

37. The method of claim 30, before electrically connecting the semiconductor chip to the metal layer, further comprising forming a surface finish on the metal layer.

38. The method of claim 30, wherein the metal layer is made of copper.
